(19) United States
(12) Patent Application Publication
(10) Pub. No.: US 2021/0103002 A1
(43) Pub. Date: Apr. 8, 2021

(54) Method and Apparatus for Estimating State of Charge of Battery

(71) Applicant: Huawei Technologies Co., Ltd., Shenzhen (CN)

(72) Inventors: Juan Li, Shenzhen (CN); Hui Li, Shenzhen (CN); Tuanbao Fan, Shanghai (CN); Yangxing Li, Shenzhen (CN)

(21) Appl. No.: 17/126,895

(22) Filed: Dec. 18, 2020

Related U.S. Application Data
(63) Continuation of application No. PCT/CN2019/088992, filed on May 29, 2019.

(30) Foreign Application Priority Data
Jun. 19, 2018 (CN) 201810634553.0

(51) Int. Cl. G01R 31/3842; G01R 31/389

(52) U.S. Cl. CPC G01R 31/3842; G01R 31/389

(57) ABSTRACT

A method and apparatus include obtaining, during a preconfigured time interval, a current-moment charge/discharge current, a current-moment temperature, a current-moment coulomb capacity, and a previous-moment state of charge (SOC) value of a battery, obtaining a discharge duration of the battery, determining a current-moment internal resistance response type of the battery based on the discharge duration, determining current-moment internal resistance data of the battery based on the current-moment internal resistance response type, the current-moment temperature, the current-moment charge/discharge current, and the previous-moment SOC value, determining a current-moment unusable capacity of the battery based on the current-moment internal resistance data, the current-moment charge/discharge current, and the current-moment temperature, and determining a current-moment SOC value of the battery based on the current-moment coulomb capacity and the current-moment unusable capacity.

### CROSS-REFERENCE TO RELATED APPLICATIONS

This application is a continuation of International Patent Application No. PCT/CN2019/088992 filed on May 29, 2019, which claims priority to Chinese Patent Application No. 201810634553.0 filed on Jun. 19, 2018. The disclosures of the aforementioned applications are hereby incorporated by reference in their entireties.

### TECHNICAL FIELD

This application relates to the field of battery management, and in particular, to a method and apparatus for estimating a state of charge (SOC) of a battery.

### BACKGROUND

An SOC of a battery is one of main parameters of a battery status, and a value of the SOC is defined as a percentage of a residual capacity of a battery in a total capacity of the battery. For a battery management system (BMS), it is difficult to determine the SOC of the battery due to the following reasons. The SOC of the battery cannot be directly measured, but can only be indirectly estimated by measuring external parameters such as a current, a voltage, and a temperature, and is affected by a plurality of factors such as a charge/discharge rate of the battery, a temperature, a self-discharge rate, an aging service life, a discharge cutoff voltage of the battery, and an internal resistance. Therefore, it is difficult to accurately estimate the SOC. In addition, the battery is a quite complex electrochemical system, and an internal electrochemical relationship of the battery is a non-linear relationship. Therefore, it is difficult to predict an internal state of the battery by establishing a relationship model using a detected limited external feature.

In an existing solution, a method and system for estimating an SOC of a power battery are provided. A Thevenin equivalent circuit model is selected, pulse current excitation is applied to the power battery, an output voltage and current data of the power battery are collected, and a pulse current excitation response curve is obtained based on a relationship between an output voltage and a time. The excitation response curve is divided into three segments: segments A, B, and C. A time constant is obtained based on the segment A of the excitation response curve with reference to a zero-input response expression of a resistance-capacitance loop and a least square method. Based on the segment B of the excitation response curve with reference to a zero-state response expression of the resistance-capacitance loop, a polarization resistance and a polarization capacitance are obtained by substituting the time constant into the zero-state response expression and using the least square method. An ohmic internal resistance is obtained based on the segment C of the excitation response curve according to the Ohm's law. An estimated value of the SOC of the power battery is obtained based on the polarization resistance, the polarization capacitance, and the ohmic internal resistance using an extended Kalman filtering algorithm.

A response time of each application greatly varies (measured in a level from milliseconds (ms) to minutes) with a user use requirement and habit. With time increasing, an ohmic internal resistance, a charge transfer resistance, and a diffusional impedance of a battery sequentially appear and are accumulated to obtain a total internal resistance of the battery. The total internal resistance of the battery also varies with time. In the existing solution, impact of the charge transfer resistance and the diffusional impedance on the total internal resistance of the battery is not considered, and consequently the calculated estimated value of the SOC of the battery is inaccurate.

### SUMMARY

Embodiments of this application provide a method and apparatus for estimating an SOC of a battery, to estimate an SOC of a battery according to a battery internal resistance model with higher accuracy, thereby improving accuracy of an estimated value of the SOC of the battery.

A first aspect of this application provides a method for estimating an SOC of a battery. The method includes obtaining, at a preconfigured time interval, a current-moment charge/discharge current, a current-moment temperature, a current-moment coulomb capacity, and a previous-moment SOC value of a to-be-measured battery in real time, where the preconfigured time interval is duration between a previous moment and a current moment, and the preconfigured time interval is preconfigured, obtaining discharge duration of the to-be-measured battery, where the discharge duration is duration of a charge/discharge current, determining a current-moment internal resistance response type of the to-be-measured battery based on the discharge duration, determining current-moment internal resistance data of the to-be-measured battery based on the current-moment internal resistance response type, the current-moment temperature, the current-moment charge/discharge current, and the previous-moment SOC value, determining a current-moment unusable capacity of the to-be-measured battery based on the current-moment internal resistance data, the current-moment charge/discharge current, and the current-moment temperature, where the unusable capacity is an SOC value when the to-be-measured battery cannot release a capacity, and determining a current-moment SOC value of the to-be-measured battery based on the current-moment coulomb capacity and the current-moment unusable capacity. A more accurate battery internal resistance model is established based on impact of a temperature, an SOC, a current, and discharge duration on a resistance of a battery. Accurate internal resistance data of the to-be-measured battery is obtained based on an internal resistance response type of the to-be-measured battery and the more accurate battery internal resistance model. Then, an unusable capacity of the battery is calculated based on the internal resistance data such that a current SOC of the battery is accurately estimated.

In a possible design, in a first implementation of the first aspect of the embodiments of this application, determining a current-moment internal resistance response type of the to-be-measured battery based on the discharge duration includes determining the current-moment internal resistance response type of the to-be-measured battery based on the discharge duration and a preconfigured first correspondence, where the first correspondence is used to indicate a correspondence between the discharge duration of the to-be-measured battery and the internal resistance response type of the to-be-measured battery. The process of determining the corresponding internal resistance response type based on the correspondence between the discharge duration of the to-be-measured battery and the internal resistance response type of the to-be-measured battery and based on a current-moment discharge duration is refined, thereby increasing the implementation of this application.

In a possible design, in a second implementation of the first aspect of the embodiments of this application, the first correspondence includes, when the discharge duration is less than or equal to a first threshold, the internal resistance response type is a first response type, and the first response type includes an ohmic resistance, when the discharge duration is greater than a first threshold and less than or equal to a second threshold, the internal resistance response type is a second response type, and the second response type includes an ohmic resistance and a charge transfer resistance, or when the discharge duration is greater than a second threshold, the internal resistance response type is a third response type, and the third response type includes an ohmic resistance, a charge transfer resistance, and a diffusional impedance. The relationship between the discharge duration and the internal resistance response type is refined, and a correspondence between a length of the discharge duration and the internal resistance response type is specified.

In a possible design, in a third implementation of the first aspect of the embodiments of this application, determining current-moment internal resistance data of the to-be-measured battery based on the current-moment internal resistance response type, the current-moment temperature, the current-moment charge/discharge current, and the previous-moment SOC value includes determining a second correspondence based on the first response type, where the second correspondence is used to indicate a correspondence between the ohmic resistance of the to-be-measured battery, and a temperature and an SOC value that are of the to-be-measured battery, and determining the current-moment internal resistance data of the to-be-measured battery based on the second correspondence, the current-moment temperature, the current-moment charge/discharge current, and the previous-moment SOC value, where the internal resistance data is a current-moment ohmic resistance. The process of determining the current-moment ohmic resistance of the to-be-measured battery is refined, thereby increasing the implementation of this application.

In a possible design, in a fourth implementation of the first aspect of the embodiments of this application, the determining current-moment internal resistance data of the to-be-measured battery based on the current-moment internal resistance response type, the current-moment temperature, the current-moment charge/discharge current, and the previous-moment SOC value includes determining a second correspondence and a third correspondence based on the second response type, where the second correspondence is used to indicate a correspondence between the ohmic resistance of the to-be-measured battery, and a temperature and an SOC value that are of the to-be-measured battery, and the third correspondence is used to indicate a correspondence between the charge transfer resistance of the to-be-measured battery, and the temperature, the SOC, and the charge/discharge current that are of the to-be-measured battery, and determining the current-moment internal resistance data of the to-be-measured battery based on the second correspondence, the third correspondence, the current-moment temperature, the current-moment charge/discharge current, and the previous-moment SOC value, where the internal resistance data is a sum of a current-moment ohmic resistance and a current-moment charge transfer resistance. The process of determining the current-moment ohmic resistance and the current-moment charge transfer resistance of the to-be-measured battery is refined, thereby increasing the implementation of this application.

In a possible design, in a fifth implementation of the first aspect of the embodiments of this application, the determining current-moment internal resistance data of the to-be-measured battery based on the current-moment internal resistance response type, the current-moment temperature, the current-moment charge/discharge current, and the previous-moment SOC value includes determining a second correspondence, a third correspondence, and a fourth correspondence based on the third response type, where the second correspondence is used to indicate a correspondence between the ohmic resistance of the to-be-measured battery, and a temperature and an SOC value that are of the to-be-measured battery, the third correspondence is used to indicate a correspondence between the charge transfer resistance of the to-be-measured battery, and the temperature, the SOC, and the charge/discharge current that are of the to-be-measured battery, and the fourth correspondence is used to indicate a correspondence between the diffusional impedance of the to-be-measured battery, and the temperature, the SOC value, and the charge/discharge current that are of the to-be-measured battery, and determining the current-moment internal resistance data of the to-be-measured battery based on the second correspondence, the third correspondence, the fourth correspondence, the current-moment temperature, the current-moment charge/discharge current, and the previous-moment SOC value, where the internal resistance data is a sum of a current-moment ohmic resistance, a current-moment charge transfer resistance, and a current-moment diffusional impedance. The process of determining the current-moment ohmic resistance, the current-moment charge transfer resistance, and the current-moment diffusional impedance of the to-be-measured battery is refined, thereby increasing the implementation of this application.

In a possible design, in a sixth implementation of the first aspect of the embodiments of this application, determining a current-moment unusable capacity of the to-be-measured battery based on the current-moment internal resistance data, the current-moment charge/discharge current, and the current-moment temperature includes determining a current-moment internal resistance voltage of the to-be-measured battery based on the current-moment internal resistance data and the current-moment charge/discharge current, where the internal resistance voltage is a voltage loss caused by an internal resistance of the to-be-measured battery, determining a current-moment unusable voltage of the to-be-measured battery based on the current-moment internal resistance voltage and a preconfigured cutoff voltage, and determining the current-moment unusable capacity of the to-be-measured battery based on the current-moment unusable voltage, the current-moment temperature, and a preconfigured fifth correspondence, where the fifth correspondence is used to indicate a correspondence between an open-circuit voltage of the to-be-measured battery, and the temperature and the SOC value that are of the to-be-measured battery. The process of determining the unusable capacity is described in detail, making steps of this application more complete and more logical.

In a possible design, in a seventh implementation of the first aspect of the embodiments of this application, the determining a current-moment SOC value of the to-be-measured battery based on the current-moment coulomb capacity and the current-moment unusable capacity includes determining an initial capacity based on a preconfigured full charge capacity, the previous-moment SOC value, and the fifth correspondence, where the initial capacity is a previous-moment capacity of the to-be-measured battery, determining a current-moment residual capacity of the to-be-measured battery based on the initial capacity, the current-moment coulomb capacity, and the current-moment unusable capacity, and determining the current-moment SOC value of the to-be-measured battery based on the current-moment residual capacity, the preconfigured full charge capacity, and the current-moment unusable capacity. The process of estimating the SOC value is described in detail, making the process of estimating the SOC easier to implement.

A second aspect of this application provides an apparatus for estimating an SOC of a battery. The estimation apparatus includes a current sensor, a temperature sensor, a coulombmeter, a timer, a memory, and a processor, where the current sensor is configured to obtain a charge/discharge current of a to-be-measured battery in real time and transmit the charge/discharge current to the processor, the temperature sensor is configured to obtain a temperature of the to-be-measured battery in real time and transmit the temperature to the processor, the coulombmeter is configured to accumulate currents flowing through the to-be-measured battery to obtain a current-moment coulomb capacity, and transmit the current-moment coulomb capacity to the processor, the timer is configured to obtain discharge duration of the to-be-measured battery and transmit the discharge duration to the processor, the memory is configured to store parameter information of the to-be-measured battery, where the parameter information includes a previous-moment SOC value, and the processor is configured to estimate a current-moment SOC value of the to-be-measured battery based on the parameter information, a current-moment charge/discharge current, a current-moment temperature, and the current-moment coulomb capacity. Specific hardware structural composition of the apparatus for estimating an SOC of a battery is provided, and the functions of all hardware structures are described.

In a possible design, in a first implementation of the second aspect in the embodiments of this application, the parameter information further includes a first correspondence, where the first correspondence is used to indicate a correspondence between the discharge duration of the to-be-measured battery and an internal resistance response type of the to-be-measured battery. The first correspondence stored in the memory is added, thereby increasing the implementation of this application.

In a possible design, in a second implementation of the second aspect in the embodiments of this application, the parameter information further includes a second correspondence, a third correspondence, and a fourth correspondence. The second correspondence is used to indicate a correspondence between an ohmic resistance of the to-be-measured battery, and a temperature and an SOC value that are of the to-be-measured battery. The third correspondence is used to indicate a correspondence between a charge transfer resistance of the to-be-measured battery, and the temperature, the SOC, and the charge/discharge current. The fourth correspondence is used to indicate a correspondence between a diffusional impedance of the to-be-measured battery, and the temperature, the SOC value, and the charge/discharge current that are of the to-be-measured battery. The second correspondence, the third correspondence, and the fourth correspondence stored in the memory are added, thereby increasing the implementation of this application.

A third aspect of this application provides an apparatus for estimating an SOC of a battery. The estimation apparatus includes a first obtaining unit configured to obtain, at a preconfigured time interval, a current-moment charge/discharge current, a current-moment temperature, a current-moment coulomb capacity, and a previous-moment SOC value of a to-be-measured battery in real time, where the preconfigured time interval is duration between a previous moment and a current moment, a second obtaining unit configured to obtain discharge duration of the to-be-measured battery, where the discharge duration is duration of a charge/discharge current, a first determining unit configured to determine a current-moment internal resistance response type of the to-be-measured battery based on the discharge duration, a second determining unit configured to determine current-moment internal resistance data of the to-be-measured battery based on the current-moment internal resistance response type, the current-moment temperature, the current-moment charge/discharge current, and the previous-moment SOC value, a third determining unit configured to determine a current-moment unusable capacity of the to-be-measured battery based on the current-moment internal resistance data, the current-moment charge/discharge current, and the current-moment temperature, where the unusable capacity is an SOC value when the to-be-measured battery cannot release a capacity, and a fourth determining unit configured to determine a current-moment SOC value of the to-be-measured battery based on the current-moment coulomb capacity and the current-moment unusable capacity. A more accurate battery internal resistance model is established based on impact of a temperature, an SOC, a current, and discharge duration on a resistance of a battery. Accurate internal resistance data of the to-be-measured battery is obtained based on an internal resistance response type of the to-be-measured battery and the more accurate battery internal resistance model. Then, an unusable capacity of the battery is calculated based on the internal resistance data such that a current SOC of the battery is accurately estimated.

In a possible design, in a first implementation of the third aspect of the embodiments of this application, the first determining unit is further configured to determine the current-moment internal resistance response type of the to-be-measured battery based on the discharge duration and a preconfigured first correspondence, where the first correspondence is used to indicate a correspondence between the discharge duration of the to-be-measured battery and the internal resistance response type of the to-be-measured battery. The process of determining a corresponding internal resistance response based on the correspondence between the discharge duration of the to-be-measured battery and the internal resistance response type of the to-be-measured battery and based on a current-moment discharge duration is refined, thereby increasing the implementation of this application.

In a possible design, in a second implementation of the third aspect of the embodiments of this application, the first correspondence includes, when the discharge duration is less than or equal to a first threshold, the internal resistance response type is a first response type, and the first response type includes an ohmic resistance, when the discharge duration is greater than a first threshold and less than or equal to a second threshold, the internal resistance response type is a second response type, and the second response type includes an ohmic resistance and a charge transfer resistance, or when the discharge duration is greater than a second threshold, the internal resistance response type is a third response type, and the third response type includes an ohmic resistance, a charge transfer resistance, and a diffusional impedance. The relationship between the discharge duration and the internal resistance response type is refined, and a correspondence between a length of the discharge duration and the internal resistance response type is specified.

In a possible design, in a third implementation of the third aspect of the embodiments of this application, the second determining unit is further configured to determine a second correspondence based on the first response type, where the second correspondence is used to indicate a correspondence between the ohmic resistance of the to-be-measured battery, and a temperature and an SOC value that are of the to-be-measured battery, and determine the current-moment internal resistance data of the to-be-measured battery based on the second correspondence, the current-moment temperature, the current-moment charge/discharge current, and the previous-moment SOC value, where the internal resistance data is a current-moment ohmic resistance, or determine a second correspondence and a third correspondence based on the second response type, where the second correspondence is used to indicate a correspondence between the ohmic resistance of the to-be-measured battery, and a temperature and an SOC value that are of the to-be-measured battery, and the third correspondence is used to indicate a correspondence between the charge transfer resistance of the to-be-measured battery, and the temperature, the SOC, and the charge/discharge current that are of the to-be-measured battery, and determine the current-moment internal resistance data of the to-be-measured battery based on the second correspondence, the third correspondence, the current-moment temperature, the current-moment charge/discharge current, and the previous-moment SOC value, where the internal resistance data is a sum of a current-moment ohmic resistance and a current-moment charge transfer resistance, or determine a second correspondence, a third correspondence, and a fourth correspondence based on the third response type, where the second correspondence is used to indicate a correspondence between the ohmic resistance of the to-be-measured battery, and a temperature and an SOC value that are of the to-be-measured battery, the third correspondence is used to indicate a correspondence between the charge transfer resistance of the to-be-measured battery, and the temperature, the SOC, and the charge/discharge current that are of the to-be-measured battery, and the fourth correspondence is used to indicate a correspondence between the diffusional impedance of the to-be-measured battery, and the temperature, the SOC value, and the charge/discharge current that are of the to-be-measured battery, and determine the current-moment internal resistance data of the to-be-measured battery based on the second correspondence, the third correspondence, the fourth correspondence, the current-moment temperature, the current-moment charge/discharge current, and the previous-moment SOC value, where the internal resistance data is a sum of a current-moment ohmic resistance, a current-moment charge transfer resistance, and a current-moment diffusional impedance. The process of determining the current-moment ohmic resistance, the current-moment charge transfer resistance, and the current-moment diffusional impedance of the to-be-measured battery is refined, thereby increasing the implementation of this application.

In a possible design, in a fourth implementation of the third aspect of the embodiments of this application, the third determining unit is further configured to determine a current-moment internal resistance voltage of the to-be-measured battery based on the current-moment internal resistance data and the current-moment charge/discharge current, where the internal resistance voltage is a voltage loss caused by an internal resistance of the to-be-measured battery, determine a current-moment unusable voltage of the to-be-measured battery based on the current-moment internal resistance voltage and a preconfigured cutoff voltage, and determine the current-moment unusable capacity of the to-be-measured battery based on the current-moment unusable voltage, the current-moment temperature, and a preconfigured fifth correspondence, where the fifth correspondence is used to indicate a correspondence between an open-circuit voltage of the to-be-measured battery, and the temperature and the SOC value that are of the to-be-measured battery. The process of determining the unusable capacity is described in detail, making steps of this application more complete and more logical.

In a possible design, in a fifth implementation of the third aspect of the embodiments of this application, the fourth determining unit is further configured to determine an initial capacity based on a preconfigured full charge capacity, the previous-moment SOC value, and the fifth correspondence, where the initial capacity is a previous-moment capacity of the to-be-measured battery, determine a current-moment residual capacity of the to-be-measured battery based on the initial capacity, the current-moment coulomb capacity, and the current-moment unusable capacity, and determine the current-moment SOC value of the to-be-measured battery based on the current-moment residual capacity, the preconfigured full charge capacity, and the current-moment unusable capacity. The process of estimating an SOC is described in detail, making the process of estimating the SOC easier to implement.

A fourth aspect of this application provides a terminal, including a battery, and an apparatus for estimating an SOC of a battery, where the apparatus for estimating an SOC of a battery is the apparatus for estimating an SOC of a battery according to any one of the second aspect and the implementations of the second aspect or according to any one of the third aspect and the implementations of the third aspect.

A fifth aspect of this application provides a computer-readable storage medium. The computer-readable storage medium stores an instruction, and when the instruction is run on a computer, the computer is enabled to perform the method in the foregoing aspects.

A sixth aspect of this application provides a computer program product including an instruction. When the computer program product is run on a computer, the computer is enabled to perform the method in the foregoing aspects.

### BRIEF DESCRIPTION OF DRAWINGS

FIG. 1A is a schematic diagram of impact of a temperature of a battery on a resistance of the battery.

FIG. 1B is a schematic diagram of impact of an SOC of a battery and a current on a resistance of the battery.

FIG. 1C is a schematic diagram of impact of discharge duration on a resistance of a battery.

FIG. 2 is a schematic diagram of an embodiment of a method for estimating an SOC of a battery according to an embodiment of this application.

FIG. 3 is a schematic diagram of a second-order equivalent circuit according to an embodiment of this application.

FIG. 4 is a schematic diagram of a third-order equivalent circuit according to an embodiment of this application.

FIG. 5 is a schematic diagram of an embodiment of an apparatus for estimating an SOC of a battery according to an embodiment of this application.

FIG. 6 is another schematic diagram of an embodiment of a method for estimating an SOC of a battery according to an embodiment of this application.

### DESCRIPTION OF EMBODIMENTS

Embodiments of this application provide a method and an apparatus for estimating an SOC of a battery, to estimate an SOC of a battery according to a battery internal resistance model with higher accuracy. This improves accuracy of an estimated value of the SOC of the battery.

To make a person skilled in the art understand the technical solutions in this application better, the following describes the embodiments of this application with reference to the accompanying drawings in the embodiments of this application.

In this application, the terms “first”, “second”, and the like are intended to distinguish between similar objects but do not necessarily indicate a specific order or sequence. Moreover, the terms “include”, “have” and any other variants in this application mean to cover the non-exclusive inclusion, for example, a process, method, system, product, or device that includes a list of steps or units is not necessarily limited to those units, but may include other units not expressly listed or inherent to such a process, method, system, product, or device.

In an existing solution, a method for measuring an internal resistance of a battery is provided. Discharge performance tests of a first battery are conducted at various ambient temperatures to obtain current values and voltage values that are corresponding to different states of charge. In different states of charge, corresponding current values and voltage values are calculated according to a battery equivalent circuit model, to obtain direct current internal resistances corresponding to the different states of charge. Polynomial fitting is performed based on the direct current internal resistances corresponding to the different states of charge at the various ambient temperatures, to establish a mathematical model for estimating the direct current internal resistance. The mathematical model indicates a relationship between a direct current internal resistance, an SOC, and a temperature. When an ambient temperature and an SOC of the second battery are known, a direct current internal resistance of a second battery is estimated using the mathematical model. Therefore, the mathematical model for estimating the direct current internal resistance is established, to estimate a direct current resistance based on a temperature and an SOC of a battery. This improves accuracy of estimating the direct current internal resistance of the battery.

It may be understood that an internal resistance of a battery is affected by a plurality of factors in the following:

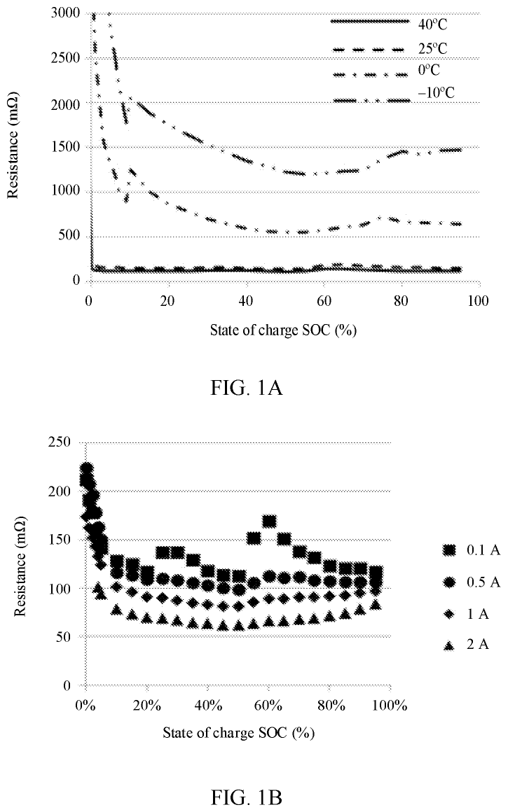

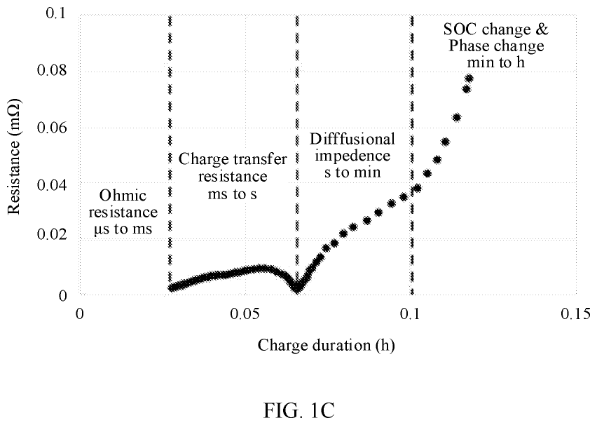

1. The internal resistance of the battery gradually increases with temperature decreasing. Especially in a low temperature environment, the internal resistance of the battery increases dramatically, as shown in FIG. 1A.

2. Within a range from 10% of an SOC to 100% of the SOC, the internal resistance of the battery fluctuates slightly. However, when the SOC decreases to a value below 10% of the SOC, the internal resistance of the battery increases dramatically, as shown in FIG. 1B.

3. A response time of each application greatly varies (in a level from ms to min) with a user use requirement and habit. With time increasing, an ohmic internal resistance, a charge transfer resistance, and a diffusional impedance of the battery sequentially appear and are accumulated to obtain a total internal resistance of the battery. The total internal resistance of the battery also varies with time, as shown in FIG. 1C.

4. As there are various applications on a mobile terminal product, different applications have different peak currents and average currents when the applications are run. Generally, the internal resistance of the battery decreases with current increasing, as shown in FIG. 1B.

How to accurately obtain the internal resistance of the battery is crucial to accurately estimating an SOC of the battery. In the existing solution, by considering only two factors a temperature and an SOC, a two-dimensional data table for an internal capacitance and a temperature and an SOC is established. However, impact of factors such as a current and a time on the internal resistance of the battery is not considered, and consequently an estimated SOC value of the battery is inaccurate. Therefore, this application provides a method and an apparatus for estimating an SOC of a battery, to estimate an SOC of a battery according to a battery internal resistance model with higher accuracy. This improves accuracy of the estimated SOC value of the battery. It should be noted that, in the battery internal resistance model, impact of factors such as a temperature, an SOC, a current, and a time on the internal resistance of the battery is considered. Therefore, the obtained internal resistance of the battery is more accurate, and a more accurate SOC value is obtained through estimation.

For ease of description, in the embodiments of this application, a lithium battery is used as an example for description. The solutions of this application may also be applied to a battery of another type, including but not limited to the lithium battery. For example, the solutions of this application may also be applied to a lithium metal-air battery, a lead-acid battery, a nickel-metal hydride battery, a nickel-cadmium battery, or the like. This is not limited herein.

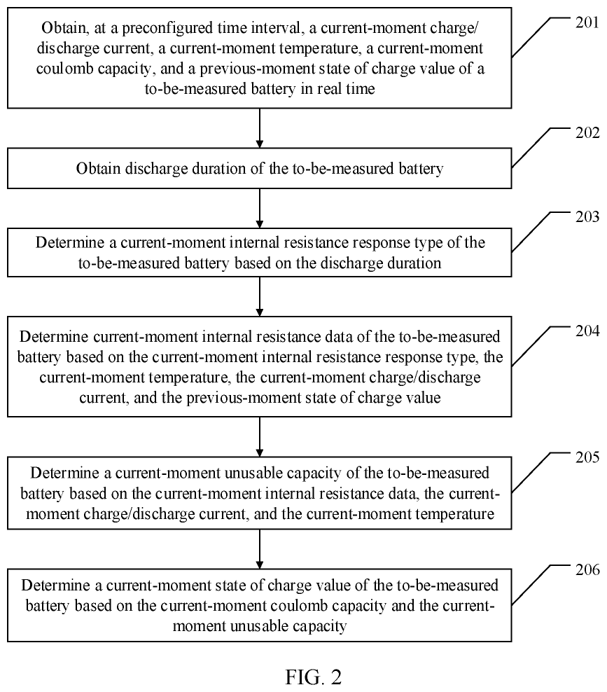

For ease of understanding, the following describes a specific procedure in the embodiments of this application. Referring to FIG. 2, an embodiment of a method for estimating an SOC of a battery according to an embodiment of this application includes the following steps.

201. Obtain, at a preconfigured time interval, a current-moment charge/discharge current, a current-moment temperature, a current-moment coulomb capacity, and a previous-moment SOC value of a to-be-measured battery in real time.

An apparatus for estimating an SOC of a battery obtains, at the preconfigured time interval, the current-moment charge/discharge current, the current-moment temperature, the current-moment coulomb capacity, and the previous-moment SOC value of the to-be-measured battery in real time. The preconfigured time interval is duration between a previous moment and a current moment. The coulomb capacity is total consumed capacities of the to-be-measured battery from the previous moment to the current moment.

Further, the apparatus for estimating an SOC of a battery obtains current-moment status information of the to-be-measured battery every three seconds (s). The status information includes the current-moment charge/discharge current, the current-moment temperature, and the current-moment coulomb capacity of the to-be-measured battery. For example, the apparatus for estimating an SOC of a battery starts timing from the 0^{th} second. When a recorded time is the 3^{rd} second, the apparatus for estimating an SOC of a battery obtains a charge/discharge current, a temperature, and a coulomb capacity of the to-be-measured battery connected to the apparatus for estimating an SOC of a battery. When a recorded time is the 6^{th} second, the apparatus for estimating an SOC of a battery obtains a charge/discharge current, a temperature, and a coulomb capacity of the to-be-measured battery again. The apparatus for estimating an SOC of a battery obtains the previous-moment SOC value. For example, if the current moment is the 6^{th} second, the apparatus for estimating an SOC of a battery obtains an SOC value of the to-be-measured battery at the 3^{rd} second. The SOC value is preconfigured and stored in the apparatus for estimating an SOC of a battery.

It may be understood that status information of the to-be-measured battery at different moments is not completely the same. For example, when a time is a second 3, the charge/discharge current of the to-be-measured battery may be 0.1 amperes (A), the temperature is 40 degree Celsius (° C.), and the coulomb capacity is 0.3 coulombs (C). When a time is a second 6, the charge/discharge current of the to-be-measured battery may be 0.1 A, the temperature is 40° C., and the coulomb capacity is 0.6 C.

It should be noted that the apparatus for estimating an SOC of a battery may set the time interval based on an actual requirement. For example, the time interval may be two s, four s, eight s, or the like, or may be one minute, five minutes, or the like. This is not limited herein.

202. Obtain discharge duration of the to-be-measured battery.

The apparatus for estimating an SOC of a battery obtains the discharge duration of the to-be-measured battery, and the discharge duration is duration, from a start moment to the current moment, in which the to-be-measured battery continuously discharges.

Each time interval is a detection period, and the discharge duration may be duration of a charge/discharge current that is longer than the detection period, or the discharge duration may be duration of a charge/discharge current that is shorter than the detection period. There is no association relationship between the discharge duration and the detection period. Duration from a moment at which discharge starts to the current moment is used as the discharge duration. The charge/discharge current may be an average current or a peak current. Discharge duration varies with an application scenario. For example, when a terminal to which the to-be-measured battery belongs is in a power-on scenario, the peak current is 3000 milliamperes (mA), duration of the peak current is 800 ms, the average current is 1500 mA, and duration of the average current is 20000 ms. If the average current is used as the charge/discharge current, the discharge duration is 20000 ms, or if the peak current is used as the charge/discharge current, the discharge duration is 800 ms. When the terminal to which the to-be-measured battery belongs is in a power-off scenario, the peak current is 1500 mA, and duration of the peak current is 200 ms, the average current is 600 mA, and duration of the average current is 5200 ms. If the average current is used as the charge/discharge current, the discharge duration is 5200 ms, or if the peak current is used as the charge/discharge current, the discharge duration is 200 ms.

It should be noted that the peak current or the average current is selected as the charge/discharge current based on the specified time interval. For example, when the preconfigured time interval is three s, the peak current is used as the charge/discharge current, and duration of the peak current in different application scenarios is within three s. When the preconfigured time interval is 60 s, the average current is used as the charge/discharge current, and duration of the average current in different application scenarios is within 60 s. In this way, different application scenarios are distinguished between each other based on the discharge duration.

203. Determine a current-moment internal resistance response type of the to-be-measured battery based on the discharge duration.

The apparatus for estimating an SOC of a battery determines the current-moment internal resistance response type of the to-be-measured battery based on the discharge duration. Further, the apparatus for estimating an SOC of a battery determines the current-moment internal resistance response type of the to-be-measured battery based on the discharge duration and a preconfigured first correspondence. The first correspondence is used to indicate a correspondence between the discharge duration of the to-be-measured battery and the internal resistance response type of the to-be-measured battery.

It should be noted that the current-moment internal resistance response type of the to-be-measured battery is determined based on the discharge duration. When the discharge duration is measured in ms, the internal resistance response type of the to-be-measured battery is a first response type, and the first response type includes an ohmic resistance. When the discharge duration is measured in s, the internal resistance response type of the to-be-measured battery is a second response type, and the second response type includes an ohmic resistance and a charge transfer resistance. When the discharge duration is measured in minutes, the internal resistance response type of the to-be-measured battery is a third response type, and the third response type includes an ohmic resistance, a charge transfer resistance, and a diffusional impedance. As the discharge duration increases, a resistance of the to-be-measured battery also increases. A person skilled in the art may obtain the correspondence according to common knowledge in the art. Details are not described herein.

For example, in a product test, peak current values and average current values in application scenarios, and duration in the scenarios are listed in Table 1. An example in which the average current is used as the charge/discharge current is used for description. When an operation such as taking photos in standard mode or sliding on the home screen is performed, and when discharge duration of the average current is less than or equal to a first threshold, the first threshold may be 1000 ms, that is, when the duration of the average current is from 1 millisecond to 1000 ms, there is only an ohmic resistance response, and the internal resistance response type of the to-be-measured battery is the ohmic resistance response. When an operation such as exiting from a standby state to enter the home screen or powering off is performed, and when discharge duration of the average current is greater than a first threshold and less than or equal to a second threshold, the second threshold is 10000 ms, that is, when the duration of the average current is from 1000 ms to 10000 ms, there is still a charge transfer resistance response after an ohmic resistance response in the to-be-measured battery, and the internal resistance response type of the to-be-measured battery is the ohmic resistance response and the charge transfer resistance response. When an operation such as answering a call, browsing a web page, playing back a local video, playing game at a maximum loudspeaker volume, performing navigation at a maximum loudspeaker volume, and powering on is performed, the duration of the average current of the to-be-measured battery is greater than a second threshold, that is, when the duration of the average current is at least 10000 ms, in addition to an ohmic resistance response and a charge transfer resistance response, there is still a diffusional impedance response. Therefore, it is determined that the internal resistance response type is an ohmic resistance response, a charge transfer resistance response, and a diffusional impedance response. It may be understood that there may be other application scenarios, which are corresponding to different peak currents and average currents, different duration of the peak currents, and different duration of the average currents. In addition, the first threshold and the second threshold may be set according to an actual case. Details are not described herein.

TABLE 1

| | Peak | | Average | |
|---|---|---|---|---|
| Application | current/ | Duration/ | current/ | Duration/ |
| scenarios | mA | ms | mA | ms |
| Powering on | 3000 | 800 | 1500 | 20000 |
| Powering off | 1500 | 200 | 600 | 5200 |
| Exiting from a standby | 1400 | 150 | 600 | 2500 |
| state to enter the home | | | | |
| screen | | | | |
| Sliding on the home | 660 | 25 | 420 | 520 |
| screen | | | | |
| Answering a call | 2000 | 350 | 520 | 30000 |
| Browsing a web page | 1600 | 900 | 520 | 50000 |
| Taking photos in a | 4000 | 3 | 2400 | 10 |
| standard mode | | | | |
| Playing back a local | 1400 | 260 | 520 | 33000 |
| video | | | | |
| Playing game at a | 2600 | 350 | 840 | 30000 |
| maximum loudspeaker | | | | |
| volume | | | | |
| Performing navigation | 2200 | 100 | 640 | 240000 |
| at a maximum | | | | |
| loudspeaker volume | | | | |

It should be noted that, before the internal resistance response type is determined, a total internal resistance of the battery needs to be obtained based on an initial relationship table between a temperature of the battery, an SOC of the battery, and a charge/discharge current of the battery, and the total internal resistance is further divided into an ohmic resistance and a polarization resistance (that is, the charge transfer resistance and the diffusional impedance) based on different time constants using an equivalent circuit model method, to obtain an ohmic resistance model and a polarization resistance model (that is, a charge transfer resistance model and a diffusional impedance model). In this application, a model of the to-be-measured battery that needs to be invoked at the current moment is determined according to the ohmic resistance model, the charge transfer resistance model, and the diffusional impedance model.

The following describes processes of obtaining the ohmic resistance model and the polarization resistance model (the charge transfer resistance model and the diffusional impedance model).

1. The process of obtaining the ohmic resistance model is as follows:

A selected battery is tested using an open-circuit voltage method. Specific test steps are as follows:

(1) Fully charge the battery in a constant-current and constant-voltage charge mode, rest the battery for a period of time for voltage stabilization, and read a voltage V₀ at this time (for example, 100% of an SOC).

(2) Discharge the battery to a fixed SOC (for example, 95% of the SOC) by a constant current I₁, read a voltage V₁ corresponding to a moment when discharge starts (for example, when the discharge duration is 0.1 s), read a voltage V₂ corresponding to a moment when discharge ends, and rest the battery for a period of time for voltage stabilization.

(3) Repeat step (2) until the SOC of the battery drops to 0%.

(4) Change a test temperature and a charge current of the battery, to conduct a test according to steps (1) to (3), to obtain ohmic internal resistances at different temperatures, with different currents, and in different SOC conditions.

The ohmic internal resistance is calculated according to the following formula:

R₀=(V₀−V₁)I₁,

where R₀ represents an ohmic internal resistance, V₀ represents a before-charge voltage of the battery, V₁ is a voltage of the battery when charge starts, and I₁ represents the discharge current.

An obvious voltage drop generated at the moment when charge starts is caused by the ohmic internal resistance. In addition, the ohmic internal resistance R₀ does not vary with the discharge current, and the ohmic resistance model may be obtained by changing a temperature T of the battery and the SOC of the battery. For example, a relationship table between the ohmic internal resistance, the temperature T of the battery, and the SOC of the battery may be obtained, as listed in Table 2.

TABLE 2

| | Temperature T | | | | |
|---|---|---|---|---|---|
| SOC | 60° C. | 40° C. | 25° C. | . . . | −20° C. |
| 95% | 54.8 | 41.5 mΩ | 81.3 mΩ | . . . | 608.4 mΩ |
| | milliohms | | | | |
| | (mΩ) | | | | |
| 90% | 55.3 mΩ | 41.3 mΩ | 81.4 mΩ | . . . | 592.7 mΩ |
| | . . . | . . . | . . . | . . . | . . . |
| 10% | 59.6 mΩ | 44.1 mΩ | 84.6 mΩ | . . . | 573.8 mΩ |
| 5% | . . . | . . . | . . . | . . . | . . . |
| 0% | . . . | . . . | . . . | . . . | . . . |

2. The process of obtaining the polarization resistance model is as follows:

Step 1: Test a selected target battery using an open-circuit voltage method. Specific test steps are as follows:

(1) Fully charge the target battery in a constant-current and constant-voltage charge mode, rest the target battery for a period of time for voltage stabilization, and read a voltage V₀ at this time (for example, 100% of an SOC).

(2) Discharge the target battery to a fixed SOC (for example, 95% of the SOC) by a constant current I₁, read a voltage V₁ corresponding to a moment when discharge starts (for example, when the discharge duration is 0.1 s), read a voltage V₂ corresponding to a moment when discharge ends, and rest the target battery for a period of time for voltage stabilization.

(3) Repeat step (2) until the SOC of the target battery drops to 0%.

(4) Change a test temperature and a charge current of the target battery, to conduct a test according to steps (1) to (3), to obtain polarization internal resistances at different temperatures, with different currents, and in different SOC conditions.

The polarization internal resistance is calculated according to the following formula

Rₚ=(V₀−V₂)/I₁,

where R₀ represents the polarization internal resistance, V₀ represents a before-charge voltage of the target battery, V₂ represents a voltage of the target battery when charge starts, and I₁ represents the discharge current.

A total polarization internal resistance of the battery is affected by a temperature of the battery, an SOC of the battery, and a charge current. The polarization resistance model may be obtained by changing the temperature T (−30 to 60° C.) of the battery, the SOC (0 to 100%) of the battery, and the charge/discharge current I (0.01 A to 5 A). For example, a relationship table between the polarization internal resistance, the temperature T of the battery, the SOC of the battery, and the charge/discharge current I may be obtained, as listed in Table 3.

TABLE 3

| | Current | Temperature T | | | | |
|---|---|---|---|---|---|---|
| SOC | I | 60° C. | 40° C. | 25° C. | . . . | −20° C. |
| 95% | 0.01 A | 107.7 mΩ | 72.5 mΩ | 116.8 mΩ | . . . | 3370.3 mΩ |
| | 0.1 A | 78.8 mΩ | 100.5 mΩ | 116.9 mΩ | . . . | 2086.5 mΩ |
| | 0.5 A | 59.0 mΩ | 72.3 mΩ | 106.7 mΩ | . . . | 648.0 mΩ |
| | 1 A | 54.7 mΩ | 67.1 mΩ | 96.5 mΩ | . . . | — |
| | . . . | . . . | . . . | . . . | . . . | . . . |
| | 5 A | 48.0 mΩ | 57.9 mΩ | 76.6 mΩ | . . . | — |
| . . . | | | | | | |
| 10% | 0.01 A | 54.8 mΩ | 80.2 mΩ | 142.7 mΩ | . . . | 3752.1 mΩ |
| | 0.1 A | 49.6 mΩ | 98.4 mΩ | 128.6 mΩ | . . . | — |
| | 0.5 A | 53.4 mΩ | 72.8 mΩ | 116.4 mΩ | . . . | — |
| | 1 A | 58.4 mΩ | 73.7 mΩ | 101.5 mΩ | . . . | — |
| | . . . | . . . | . . . | . . . | . . . | . . . |
| | 5 A | 57.4 mΩ | 65.6 mΩ | 81.1 mΩ | . . . | — |
| . . . | | | | | | |

Step 2: Based on different time responses of battery discharge types, the total polarization internal resistance Rₚ of the battery is further divided into a charge transfer resistance and a diffusional impedance, that is, the polarization internal resistance model is divided into the charge transfer resistance model and the diffusional impedance model. For example, a relationship table between the battery charge transfer resistance or the battery diffusional impedance, and the temperature of the battery, the SOC of the battery, and the charge/discharge current may be established.

(1) Determine a sub-type of the polarization internal resistance based on the discharge duration.

A relationship between a time response, and the ohmic internal resistance, the charge transfer resistance, and the diffusional impedance is as follows The ohmic resistance is measured in a level from microseconds (μs) to ms, the charge transfer resistance is measured in a level from ms to s, and the diffusional impedance is measured in a level from s to minutes (min).

(2) Divide the polarization internal resistance according to an equivalent circuit model using a least square fitting method or a Kalman filtering algorithm.

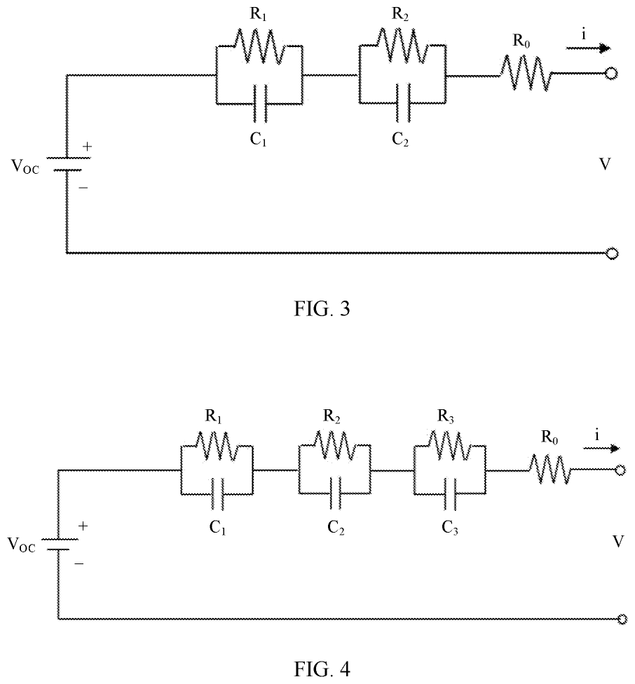

The equivalent circuit model of the battery may be a second-order equivalent circuit model, and a structure is shown in FIG. 3. R₀ represents an ohmic resistance, R₁ and C₁, and R₂ and C₂ represent polarization effects of the battery, and R₁ and R₂ are respectively corresponding to a charge transfer resistance and a diffusional impedance.

When the second-order equivalent circuit model is divided using the least square fitting method, a method for calculating the charge transfer resistance and the diffusional impedance is as follows:

When the lithium-ion battery is in a discharge state, a voltage output of the lithium-ion battery is:

$$V = {V}_{o c} - I {R}_{0} - I {R}_{1} ( 1 - {e}^{- \frac{t}{{τ}_{1}}} ) - I {R}_{2} ( 1 - {e}^{- \frac{t}{{τ}_{2}}} ) . \qquad ( 1 )$$

A selected fitting curve expression is as follows:

V=k₀+k₁e^{-λ}^{₁}^{·t}+k₂e^{-λ}^{₂}^{·t}. (2)

Fitting is performed on parameters in software using the least square fitting method, to obtain parameters k₀, k₁, k₂, λ₁, and λ₂ in Formula (2).

It can be learned from Formula (1) and Formula (2) that:

$$\begin{matrix}{R}_{1} = \frac{{k}_{1}}{I} , {R}_{2} = \frac{{k}_{2}}{I} , and & ( 3 ) \\ {C}_{1} = \frac{1}{{λ}_{1} {R}_{1}} , {C}_{2} = \frac{1}{{λ}_{2} {R}_{2}} . & ( 4 )\end{matrix}$$

Values of parameters R₁, R₂, C₁, and C₂ may be obtained according to Formula (3) and Formula (4), where R₁ represents the charge transfer resistance and R₂ represents the diffusional impedance.

When the second-order equivalent circuit model is divided using the Kalman filtering algorithm, a method for calculating the charge transfer resistance and the diffusional impedance is as follows:

For a second-order RC equivalent circuit model, an equation for a state of the battery is as follows:

$$\{ \begin{matrix}{SOC}^{′} = - \frac{η I}{3600 Q} \\ {V}_{1}^{′} = - \frac{1}{{R}_{1} {C}_{1}} {V}_{1} + \frac{1}{{C}_{1}} i , \\ {V}_{2}^{′} = - \frac{1}{{R}_{2} {C}_{2}} {V}_{2} + \frac{1}{{C}_{2}} i\end{matrix} \qquad ( 5 )$$

where Q represents a battery capacity, η represents charge/discharge efficiency, SOC represents an SOC of the battery, and V₁ and V₂ represent polarization capacitance voltage drops.

A measurement equation is as follows:

V=V_{oc}+V₁+V₂+R₀i. (6)

A relationship between an open-circuit voltage of the battery and an SOC is as follows:

$${V}_{o c} = f ( SOC ) = {{\sum }^{n}}_{j = 1} {a}_{j} S O {C}^{i} . \qquad ( 7 )$$

When a sampling period is T, the measurement equation (6) may be rewritten as:

V_{0,k}−Vₖ=p₁[Vₖ₋₁−v_{0,k-1}]+p₂[Vₖ₋₂−V_{0,k-2}]+p₃iₖ+p₄iₖ₋₁+p₅iₖ₋₂. (8)

A relationship between parameters is shown in Formula (9):

$$\{ \begin{matrix}{p}_{0} = {T}^{2} / ( {p}_{1} + {p}_{2} - 1 ) \\ a = {p}_{2} / {p}_{1} \\ b = - {p}_{0} ( {p}_{1} + 2 {p}_{2} ) / T \\ c = {p}_{0} ( {p}_{3} + {p}_{4} + {p}_{5} ) / {T}^{2} \\ d = - {p}_{0} ( {p}_{4} + 2 {p}_{5} ) / T \\ {R}_{0} = {p}_{5} / {p}_{2} \\ {R}_{1} {C}_{1} = min \{ ( b + \sqrt{{b}^{2} - 4 a} ) / 2 , ( b - \sqrt{{b}^{2} - 4 a} ) / 2 \} \\ {R}_{2} {C}_{2} = max \{ ( b + \sqrt{{b}^{2} - 4 a} ) / 2 , ( b - \sqrt{{b}^{2} - 4 a} ) / 2 \} \\ {R}_{2} = ( {R}_{2} {C}_{2} c + b {R}_{0} - {R}_{2} {C}_{2} {R}_{0} - d ) / ( {R}_{2} {C}_{2} - {R}_{1} {C}_{1} ) \\ {R}_{1} = c - {R}_{2} - {R}_{0}\end{matrix} . \qquad ( 9 )$$

For Formula (8), parameter identification may be performed using a Kalman filtering algorithm, and a state space of a model parameter may be expressed as:

xₖ=xₖ₋₁+ξₖ

yₖ=Cₖxₖ+χₖ, (10)

where ξₖ represents random interference, and χₖ represents random observation noise.

yₖ=V_{0,k}−Vₖ

Cₖ=[Vₖ₋₁−V_{0,k-1},Vₖ₋₂−V_{0,k-2},iₖ,iₖ₋₁,iₖ₋₂]

xₖ=[p_{1,k},p_{2,k},p_{3,k},p_{4,k},p_{5,k}]^{T}. (11)

Statistical characteristics of system interference ξₖ, the observation noise χₖ, and a state variable initial value x₀ are as follows:

$$\begin{matrix}E \{ {ξ}_{k} \} = 0 , E \{ {χ}_{k} \} = 0 , E \{ {x}_{0} \} = {μ}_{0} & ( 12 ) \\ E \{ {[ {x}_{0} - {μ}_{0} ] [ {x}_{0} - {μ}_{0} ]}^{T} \} = {p}_{0} \\ {C}_{o v} \{ {ξ}_{j} , {ξ}_{k} \} = \{ \begin{matrix}0 , j \neq k \\ M = diag \{ {m}_{1} , {m}_{2} , … {m}_{5} \} , j = k\end{matrix} \\ {C}_{o v} \{ {χ}_{j} , {χ}_{k} \} = \{ \begin{matrix}0 , j \neq k \\ N = \{ n \} , j = k\end{matrix} & \end{matrix}$$

where u₀ and p₀ are respectively used as a state variable and an error variance matrix initial value, to start a recursive algorithm, and a recursive process of the algorithm is as follows:

xₖ=xₖ₋₁

P_{k/k-1}=Pₖ₋₁+M

kₖ=P_{k/k-1}Cₖ^{T}[CₖP_{k/k-1}Cₖ^{T}+N]⁻¹

Pₖ=[I−kₖCₖ]P_{k/k-1}

xₖ=x_{k/k-1}+kₖyₖ−Cₖx_{k/k-1}, (13)

where yₖ represents an end voltage sampling value Vₖ, I represents an identity matrix, x_{k/k-1} represents a state variable prediction value, xₖ represents a state variable output value, P_{k/k-1} represents an error covariance prediction value, Pₖ represents an error covariance update value, and kₖ represents a filtering gain update value.

According to an optimal status estimation xₖ₊₁ that is obtained through recursion according to the Kalman filtering algorithm, a battery model parameter may be obtained with reference to Formula (9).

It should be noted that the equivalent circuit model of the battery may be a third-order equivalent circuit model. A structure of the third-order equivalent circuit model is shown in FIG. 4, where R₀ represents an ohmic resistance, R₁ and C₁, R₂ and C₂, and R₃ and C₃ represent polarization effects of the battery, and R₁, R₂, and R₃ are respectively corresponding to a charge transfer resistance, a diffusional impedance 1, and a diffusional impedance 2. A calculation method of the third-order equivalent circuit model is similar to the calculation method of the second-order equivalent circuit model. Details are not described herein again.

(3) Obtain the charge transfer resistance model and the diffusional impedance model. For example, a relationship table between a charge transfer resistance of a battery, and a temperature of the battery, an SOC of the battery, and a charge/discharge current may be established, as listed in Table 4. A relationship table between a diffusional impedance of a battery, and a temperature of the battery, an SOC of the battery, and a charge/discharge current may be established, as listed in Table 5.

TABLE 4

| | Current | Temperature T | | | | |
|---|---|---|---|---|---|---|
| SOC | I | 60° C. | 40° C. | 25° C. | . . . | −20° C. |
| 95% | 0.01 A | 21.54 mΩ | 15.225 mΩ | 25.696 mΩ | . . . | 1011.09 mΩ |
| | 0.1 A | 15.76 mΩ | 21.105 mΩ | 25.718 mΩ | . . . | 625.95 mΩ |
| | 0.5 A | 11.8 mΩ | 15.183 mΩ | 23.474 mΩ | . . . | 194.4 mΩ |
| | 1 A | 10.94 mΩ | 14.091 mΩ | 21.23 mΩ | . . . | — |
| | . . . | . . . | . . . | . . . | . . . | . . . |
| | 5 A | 9.6 mΩ | 12.159 mΩ | 16.852 mΩ | . . . | — |
| . . . | | | | | | |
| 10% | 0.01 A | 10.96 mΩ | 16.842 mΩ | 31.394 mΩ | . . . | 1125.63 mΩ |
| | 0.1 A | 9.92 mΩ | 20.664 mΩ | 28.292 mΩ | . . . | — |
| | 0.5 A | 10.68 mΩ | 15.288 mΩ | 25.608 mΩ | . . . | — |
| | 1 A | 11.68 mΩ | 15.477 mΩ | 22.33 mΩ | . . . | — |
| | . . . | . . . | . . . | . . . | . . . | . . . |
| | 5 A | 11.48 mΩ | 13.776 mΩ | 17.842 mΩ | . . . | — |
| . . . | | | | | | |

TABLE 5

| | Current | Temperature T | | | | |
|---|---|---|---|---|---|---|
| SOC | I | 60° C. | 40° C. | 25° C. | . . . | −20° C. |
| 95% | 0.01 A | 86.16 mΩ | 57.275 mΩ | 91.104 mΩ | . . . | 2359.21 mΩ |
| | 0.1 A | 63.04 mΩ | 79.395 mΩ | 91.182 mΩ | . . . | 1460.55 mΩ |
| | 0.5 A | 47.2 mΩ | 57.117 mΩ | 83.226 mΩ | . . . | 453.6 mΩ |
| | 1 A | 43.76 mΩ | 53.009 mΩ | 75.27 mΩ | . . . | — |
| | . . . | . . . | . . . | . . . | . . . | . . . |
| | 5 A | 38.4 mΩ | 45.741 mΩ | 59.748 mΩ | . . . | — |
| . . . | | | | | | |
| 10% | 0.01 A | 43.84 mΩ | 63.358 mΩ | 111.306 mΩ | . . . | 2626.47 mΩ |
| | 0.1 A | 39.68 mΩ | 77.736 mΩ | 100.308 mΩ | . . . | — |
| | 0.5 A | 42.72 mΩ | 57.512 mΩ | 90.792 mΩ | . . . | — |
| | 1 A | 46.72 mΩ | 58.223 mΩ | 79.17 mΩ | . . . | — |
| | . . . | . . . | . . . | . . . | . . . | . . . |
| | 5 A | 45.92 mΩ | 51.824 mΩ | 63.258 mΩ | . . . | — |
| . . . | | | | | | |

204. Determine current-moment internal resistance data of the to-be-measured battery based on the current-moment internal resistance response type, the current-moment temperature, the current-moment charge/discharge current, and the previous-moment SOC value.

The apparatus for estimating an SOC of a battery determines the current-moment internal resistance data of the to-be-measured battery based on the current-moment internal resistance response type, the current-moment temperature, the current-moment charge/discharge current, and the previous-moment SOC value.

It should be noted that, for different internal resistance response types, the apparatus for estimating an SOC of a battery needs to invoke different correspondences. For example, when the current-moment internal resistance response type is a first response type, a second correspondence is first determined based on the first response type, where the second correspondence is used to indicate a correspondence between an ohmic resistance of the to-be-measured battery, and a temperature and an SOC value that are of the to-be-measured battery. The current-moment internal resistance data of the to-be-measured battery is determined based on the second correspondence, the current-moment temperature, and the previous-moment SOC value, where the internal resistance data is a current-moment ohmic resistance.

For another example, when the current-moment internal resistance response type is a second response type, a second correspondence and a third correspondence are first determined based on the second response type, where the second correspondence is used to indicate a correspondence between the ohmic resistance of the to-be-measured battery, and a temperature and an SOC value that are of the to-be-measured battery, and the third correspondence is used to indicate a correspondence between the charge transfer resistance of the to-be-measured battery, and the temperature, the SOC, and the charge/discharge current that are of the to-be-measured battery. The current-moment internal resistance data of the to-be-measured battery is determined based on the second correspondence, the third correspondence, the current-moment temperature, the current-moment charge/discharge current, and the previous-moment SOC value, where the internal resistance data is a sum of a current-moment ohmic resistance and a current-moment charge transfer resistance.

For another example, when the current-moment internal resistance response type is a third response type, a second correspondence, a third correspondence, and a fourth correspondence are first determined based on the third response type, where the second correspondence is used to indicate a correspondence between the ohmic resistance of the to-be-measured battery, and a temperature and an SOC value that are of the to-be-measured battery, the third correspondence is used to indicate a correspondence between the charge transfer resistance of the to-be-measured battery, and the temperature, the SOC, and the charge/discharge current that are of the to-be-measured battery, and the fourth correspondence is used to indicate a correspondence between the diffusional impedance of the to-be-measured battery, and the temperature, the SOC value, and the charge/discharge current that are of the to-be-measured battery. The current-moment internal resistance data of the to-be-measured battery is determined based on the second correspondence, the third correspondence, the fourth correspondence, the current-moment temperature, the current-moment charge/discharge current, and the previous-moment SOC value, where the internal resistance data is a sum of a current-moment ohmic resistance, a current-moment charge transfer resistance, and a current-moment diffusional impedance. It should be noted that, when the current-moment internal resistance response type is the third response type, a polarization resistance may be obtained based on a preconfigured polarization resistance correspondence, where the polarization resistance is a sum of a charge transfer resistance and a diffusional impedance, and the preconfigured polarization resistance correspondence may be divided into the third correspondence and the fourth correspondence. A process of determining the internal resistance data is similar, and details are not described herein again.

For example, if the current-moment internal resistance response type is the first response type, Table 2 is searched for corresponding internal resistance data based on the current-moment temperature and the previous-moment SOC value. Further, if the current-moment temperature is 40° C., and the previous-moment SOC value is 90%, the ohmic resistance corresponding to the to-be-measured battery is 41.3 mΩ. For another example, if the current-moment internal resistance response type of the to-be-measured battery is the second response type, both Table 2 and Table 4 are searched for corresponding internal resistance data based on the current-moment temperature, the current-moment charge/discharge current, and the previous-moment SOC value. Further, if the current-moment temperature is 60° C., the current-moment charge/discharge current is 0.1 A, and the previous-moment SOC value is 95%, the ohmic resistance corresponding to the to-be-measured battery is 41.5 mΩ. and the charge transfer resistance corresponding to the to-be-measured battery is 21.105 mΩ. For another example, if the current-moment internal resistance response type of the to-be-measured battery is the third response type, Table 2, Table 4, and Table 5 are respectively searched for a corresponding ohmic resistance, a corresponding charge transfer resistance, and a corresponding diffusional impedance based on the current-moment temperature, the current-moment charge/discharge current, and the previous-moment SOC value. Further, if the current-moment temperature is 25° C., the current-moment charge/discharge current is 0.5 A, and the previous-moment SOC value is 95%, the ohmic resistance corresponding to the to-be-measured battery is 81.3 mΩ, the charge transfer resistance corresponding to the to-be-measured battery is 23.474 mΩ, and the diffusional impedance corresponding to the to-be-measured battery is 83.226 mΩ.

It may be understood that, Table 4 and Table 5 are obtained by dividing Table 3. When the current-moment internal resistance response type is the third response type, the polarization internal resistance may also be obtained by directly searching Table 3, and then the polarization internal resistance and the ohmic resistance that is obtained by searching Table 2 are summed up, to obtain the current-moment internal resistance data. For example, if the current-moment internal resistance response type of the to-be-measured battery is the third response type, Table 2 and Table 3 are respectively searched for a corresponding ohmic resistance and a corresponding polarization resistance based on the current-moment temperature, the current-moment charge/discharge current, and the previous-moment SOC value. Further, if the current-moment temperature is 25° C., the current-moment charge/discharge current is 0.5 A, and the previous-moment SOC value is 95%, the ohmic resistance corresponding to the to-be-measured battery is 81.3 mΩ, and the polarization resistance corresponding to the to-be-measured battery is 106.7 mΩ.

205. Determine a current-moment unusable capacity of the to-be-measured battery based on the current-moment internal resistance data, the current-moment charge/discharge current, and the current-moment temperature.

The apparatus for estimating an SOC of a battery determines the current-moment unusable capacity of the to-be-measured battery based on the current-moment internal resistance data, the current-moment charge/discharge current, and the current-moment temperature, where the unusable capacity is an SOC value when the to-be-measured battery cannot release a capacity.

Further, the apparatus for estimating an SOC of a battery determines a current-moment internal resistance voltage of the to-be-measured battery based on the current-moment internal resistance data and the current-moment charge/discharge current, determines a current-moment unusable voltage of the to-be-measured battery based on the current-moment internal resistance voltage and a preconfigured cutoff voltage, and determines the current-moment unusable capacity of the to-be-measured battery based on the current-moment unusable voltage, the current-moment temperature, and a preconfigured fifth correspondence, where the fifth correspondence is used to indicate a correspondence between the open-circuit voltage of the to-be-measured battery, and the temperature and the SOC value that are of the to-be-measured battery.

The unusable voltage may be calculated according to Formula (14):

Unusable voltage=I×R+cutoff voltage, (14)

where I represents the current-moment charge/discharge current, and R represents the internal resistance data, determined in step 204, of the to-be-measured battery. The cutoff voltage is preset according to an actual case, and different models of batteries may have different cutoff voltages. This is not limited herein.

Then, the apparatus for estimating an SOC of a battery obtains the unusable capacity based on the calculated unusable voltage and by searching the fifth correspondence, where the fifth correspondence may be a relationship table between an open-circuit voltage of the battery and a temperature of the battery, and an SOC of the battery, as listed in Table 6.

TABLE 6

| | Temperature T | | | | | |
|---|---|---|---|---|---|---|
| SOC | −20° C. | −10° C. | 0° C. | 25° C. | 40° C. | 60° C. |
| 100% | 4.3315 volts (V) | 4.3309 V | 4.3278 V | 4.3245 V | 4.3201 V | 4.3137 V |
| 95% | 4.2384 V | 4.2516 V | 4.2581 V | 4.2652 V | 4.2614 V | 4.256 V |
| 90% | 4.1724 V | 4.1894 V | 4.1987 V | 4.2096 V | 4.2055 V | 4.2004 V |
| . . . | . . . | . . . | . . . | . . . | . . . | . . . |
| 10% | 3.6993 V | 3.7016 V | 3.695 V | 3.6896 V | 3.6828 V | 3.6711 V |
| 5% | 3.642 V | 3.6657 V | 3.6658 V | 3.6754 V | 3.6642 V | 3.6329 V |
| 0% | 3.28 V | 3.3062 V | 3.284 V | 3.3754 V | 3.3389 V | 3.2079 V |

It should be noted that Table 6 lists only a part of data, and in actual application, omitted data may be obtained through calculation based on the provided data. Details are not described herein.

206. Determine a current-moment SOC value of the to-be-measured battery based on the current-moment coulomb capacity and the current-moment unusable capacity.

The apparatus for estimating an SOC of a battery determines the current-moment SOC value of the to-be-measured battery based on the current-moment coulomb capacity and the current-moment unusable capacity.

Further, the apparatus for estimating an SOC of a battery first determines an initial capacity based on the previous-moment SOC value SOCₛₜₐᵣₜ and a full charge capacity (FCC) of the to-be-measured battery, and then obtains the current-moment SOC value of the to-be-measured battery obtained through calculation using the obtained coulomb capacity (CC) and the calculated unusable capacity (UUC).

For example, the apparatus for estimating an SOC of a battery estimates the current-moment SOC value according to Formula (15):

$$SOC = \frac{S O {C}_{start} \times FCC - C C - U U C}{FCC - U U C} , \qquad ( 15 )$$

where SOCₛₜₐᵣₜ represents the previous-moment SOC, and is obtained according to Table 6, FCC represents the full charge capacity, CC represents the coulomb capacity, and UUC represents the unusable capacity.

In this embodiment of this application, first, the total internal resistance of the battery is obtained based on the initial relationship table between the temperature of the battery, the SOC of the battery, and the current of the battery, and the total internal resistance is further divided into the ohmic resistance, the charge transfer resistance, and the diffusional impedance based on different time constants using the equivalent circuit model method, to obtain a new battery internal resistance model. Factors affecting the internal resistance of the battery, such as the discharge duration and the current value are fully considered such that a more precise battery internal resistance model is established. Then, the current-moment temperature of the to-be-measured battery, the previous-moment charge of state SOC of the to-be-measured battery, and the current-moment charge/discharge current are obtained in real time. The internal resistance response type is first determined based on a current running time, then corresponding internal resistance data is extracted from the battery internal resistance model according to the foregoing condition, and the unusable capacity of the battery is accurately calculated using the internal resistance of the battery such that the current-moment SOC of the battery is accurately estimated. The SOC of the battery is estimated according to the battery internal resistance model with higher accuracy, thereby improving accuracy of an estimated value of the SOC of the battery.

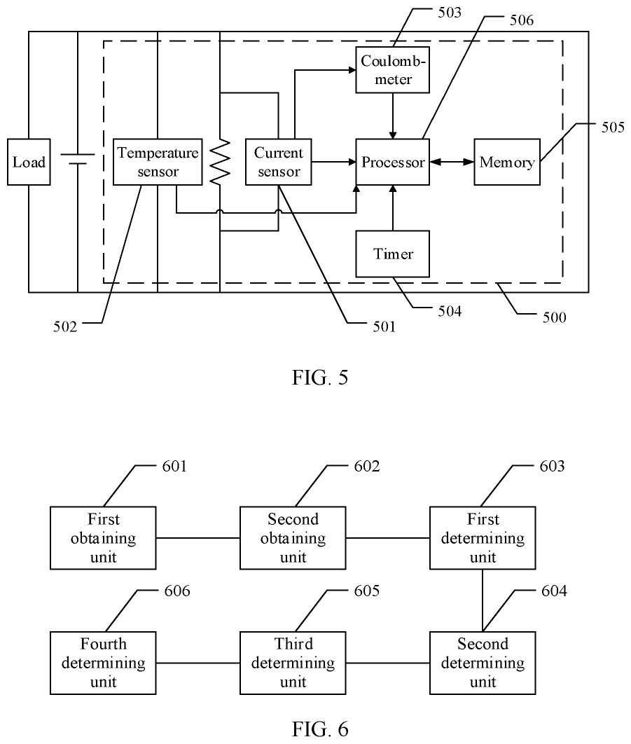

The foregoing describes the method for estimating an SOC of a battery in the embodiment of this application. The following describes an apparatus for estimating an SOC of a battery in the embodiments of this application. Referring to FIG. 5, an embodiment of an apparatus 500 for estimating an SOC of a battery according to an embodiment of this application includes a current sensor 501, a temperature sensor 502, a coulombmeter 503, a timer 504, a memory 505, and a processor 506.

The current sensor 501 is configured to obtain a charge/discharge current of a to-be-measured battery in real time and transmit the charge/discharge current to the processor 506.

The temperature sensor 502 is configured to obtain a temperature of the to-be-measured battery in real time and transmit the temperature to the processor 506.

The coulombmeter 503 is configured to accumulate currents flowing through the to-be-measured battery to obtain a current-moment coulomb capacity, and transmit the current-moment coulomb capacity to the processor 506.

The timer 504 is configured to obtain discharge duration of the to-be-measured battery and transmit the discharge duration to the processor 506.

The memory 505 is configured to store parameter information of the to-be-measured battery, where the parameter information includes a previous-moment SOC value.

The processor 506 is configured to estimate a current-moment SOC value of the to-be-measured battery based on the parameter information, a current-moment charge/discharge current, a current-moment temperature, and the current-moment coulomb capacity.

In this embodiment of this application, an SOC of a battery is estimated according to a battery internal resistance model with higher accuracy, thereby improving accuracy of an estimated value of the SOC of the battery.

In a possible implementation, the memory 505 may further store a first correspondence. The first correspondence is used to indicate a correspondence between the discharge duration of the to-be-measured battery and an internal resistance response type of the to-be-measured battery.

In a possible implementation, the memory 505 further stores a second correspondence, a third correspondence, and a fourth correspondence. The second correspondence is used to indicate a correspondence between an ohmic resistance of the to-be-measured battery, and a temperature and an SOC value that are of the to-be-measured battery. The third correspondence is used to indicate a correspondence between a charge transfer resistance of the to-be-measured battery, and the temperature, the SOC, and the charge/discharge current. The fourth correspondence is used to indicate a correspondence between a diffusional impedance of the to-be-measured battery, and the temperature, the SOC value, and the charge/discharge current that are of the to-be-measured battery.

In a possible implementation, the memory 505 may further store data information obtained by each of the current sensor 501, the temperature sensor 502, the coulombmeter 503, and the timer 504.

The processor 506 is a control center of the apparatus 500 for estimating an SOC of a battery, and may perform processing according to the specified method for estimating an SOC of a battery. The processor 506 is connected to all the parts of the entire apparatus for estimating an SOC of a battery using various interfaces and lines, and executes various functions of the apparatus for estimating an SOC of a battery and processes data by running or executing a software program and/or module stored in the memory 505 and by invoking data stored in the memory 505, to estimate an SOC value of the battery.

The memory 505 may be configured to store the software program and module. The processor 506 executes various functional applications and data processing of the apparatus 500 for estimating an SOC of a battery by running the software program and module stored in the memory 505. The memory 505 may mainly include a program storage area and a data storage area. The program storage area may store an operating system, an application program required by at least one function (for example, a first correspondence), and the like. The data storage area may store data created according to use of a device (for example, a current-moment coulomb capacity) and the like. In addition, the memory 505 may include a high-speed random-access memory (RAM), and may further include a nonvolatile memory, for example, at least one magnetic disk storage device, a flash memory, or another volatile solid-state storage device. A program and an obtained data stream in the method for estimating an SOC of a battery provided in this embodiment of this application are stored in the memory 505. When the program or the data stream needs to be used, the processor 506 invokes the program or the data stream from the memory 505.

The foregoing describes in detail the apparatus for estimating an SOC of a battery in this embodiment of this application from a perspective of hardware processing with reference to FIG. 5. The following describes in detail the apparatus for estimating an SOC of a battery in an embodiment of this application from a perspective of functional modules. Referring to FIG. 6, another embodiment of an apparatus for estimating an SOC of a battery according to an embodiment of this application includes a first obtaining unit 601 configured to obtain, at a preconfigured time interval, a current-moment charge/discharge current, a current-moment temperature, a current-moment coulomb capacity, and a previous-moment SOC value of a to-be-measured battery in real time, where the preconfigured time interval is duration between a previous moment and a current moment, a second obtaining unit 602 configured to obtain discharge duration of the to-be-measured battery, where the discharge duration is duration of a charge/discharge current, a first determining unit 603 configured to determine a current-moment internal resistance response type of the to-be-measured battery based on the discharge duration, a second determining unit 604 configured to determine current-moment internal resistance data of the to-be-measured battery based on the current-moment internal resistance response type, the current-moment temperature, the current-moment charge/discharge current, and the previous-moment SOC value, a third determining unit 605 configured to determine a current-moment unusable capacity of the to-be-measured battery based on the current-moment internal resistance data, the current-moment charge/discharge current, and the current-moment temperature, where the unusable capacity is an SOC value when the to-be-measured battery cannot release a capacity, and a fourth determining unit 606 configured to determine a current-moment SOC value of the to-be-measured battery based on the current-moment coulomb capacity and the current-moment unusable capacity.

In a possible implementation, the first determining unit 603 is further configured to determine the current-moment internal resistance response type of the to-be-measured battery based on the discharge duration and a preconfigured first correspondence, where the first correspondence is used to indicate a correspondence between the discharge duration of the to-be-measured battery and the internal resistance response type of the to-be-measured battery.

In a possible implementation, the first correspondence includes, when the discharge duration is less than or equal to a first threshold, the internal resistance response type is a first response type, and the first response type includes an ohmic resistance, when the discharge duration is greater than a first threshold and less than or equal to a second threshold, the internal resistance response type is a second response type, and the second response type includes an ohmic resistance and a charge transfer resistance, or when the discharge duration is greater than a second threshold, the internal resistance response type is a third response type, and the third response type includes an ohmic resistance, a charge transfer resistance, and a diffusional impedance.

In a possible implementation, the second determining unit 604 is further configured to determine a second correspondence based on the first response type, where the second correspondence is used to indicate a correspondence between the ohmic resistance of the to-be-measured battery, and a temperature and an SOC value that are of the to-be-measured battery, and determine the current-moment internal resistance data of the to-be-measured battery based on the second correspondence, the current-moment temperature, the current-moment charge/discharge current, and the previous-moment SOC value, where the internal resistance data is a current-moment ohmic resistance, or determine a second correspondence and a third correspondence based on the second response type, where the second correspondence is used to indicate a correspondence between the ohmic resistance of the to-be-measured battery, and a temperature and an SOC value that are of the to-be-measured battery, and the third correspondence is used to indicate a correspondence between the charge transfer resistance of the to-be-measured battery, and the temperature, the SOC, and the charge/discharge current that are of the to-be-measured battery, and determine the current-moment internal resistance data of the to-be-measured battery based on the second correspondence, the third correspondence, the current-moment temperature, the current-moment charge/discharge current, and the previous-moment SOC value, where the internal resistance data is a sum of a current-moment ohmic resistance and a current-moment charge transfer resistance, or determine a second correspondence, a third correspondence, and a fourth correspondence based on the third response type, where the second correspondence is used to indicate a correspondence between the ohmic resistance of the to-be-measured battery, and a temperature and an SOC value that are of the to-be-measured battery, the third correspondence is used to indicate a correspondence between the charge transfer resistance of the to-be-measured battery, and the temperature, the SOC, and the charge/discharge current that are of the to-be-measured battery, and the fourth correspondence is used to indicate a correspondence between the diffusional impedance of the to-be-measured battery, and the temperature, the SOC value, and the charge/discharge current that are of the to-be-measured battery, and determine the current-moment internal resistance data of the to-be-measured battery based on the second correspondence, the third correspondence, the fourth correspondence, the current-moment temperature, the current-moment charge/discharge current, and the previous-moment SOC value, where the internal resistance data is a sum of a current-moment ohmic resistance, a current-moment charge transfer resistance, and a current-moment diffusional impedance.

In a possible implementation, the third determining unit 605 is further configured to determine a current-moment internal resistance voltage of the to-be-measured battery based on the current-moment internal resistance data and the current-moment charge/discharge current, determine a current-moment unusable voltage of the to-be-measured battery based on the current-moment internal resistance voltage and a preconfigured cutoff voltage, and determine the current-moment unusable capacity of the to-be-measured battery based on the current-moment unusable voltage, the current-moment temperature, and a preconfigured fifth correspondence, where the fifth correspondence is used to indicate a correspondence between an open-circuit voltage of the to-be-measured battery, and the temperature and the SOC value that are of the to-be-measured battery.

In a possible implementation, the fourth determining unit 606 is further configured to determine an initial capacity based on a preconfigured full charge capacity, the previous-moment SOC value, and the fifth correspondence, where the initial capacity is a previous-moment capacity of the to-be-measured battery, determine a current-moment residual capacity of the to-be-measured battery based on the initial capacity, the current-moment coulomb capacity, and the current-moment unusable capacity, and determine the current-moment SOC value of the to-be-measured battery based on the current-moment residual capacity, the preconfigured full charge capacity, and the current-moment unusable capacity.

This application further provides a terminal. The terminal includes a battery, and an apparatus for estimating an SOC of a battery.

The apparatus for estimating an SOC of a battery is the apparatus for estimating an SOC of a battery according to any one of the foregoing embodiments. For a structure of the apparatus for estimating an SOC of a battery, refer to the foregoing embodiments. Details are not described herein again.

The computer program product includes one or more computer instructions. When the computer program instruction is loaded and executed on a computer, some or all of the procedures or functions according to the embodiments of this application are generated. The computer may be a general-purpose computer, a special-purpose computer, a computer network, or another programmable apparatus. The computer instructions may be stored in a computer-readable storage medium or may be transmitted from a computer-readable storage medium to another computer-readable storage medium. For example, the computer instruction may be transmitted from a website, computer, server, or data center to another website, computer, server, or data center in a wired (for example, a coaxial cable, an optical fiber, or a digital subscriber line (DSL)) or wireless (for example, infrared, radio, or microwave) manner. The computer-readable storage medium may be any usable medium accessible by a computer, or a data storage device, such as a server, a data center, or the like, integrating one or more usable media. The usable medium may be a magnetic medium (for example, a floppy disk, a hard disk, or a magnetic tape), an optical medium (for example, a digital versatile disc (DVD)), a semiconductor medium (for example, a solid-state drive (SSD)), or the like.

When the integrated unit is implemented in the form of a software functional unit and sold or used as an independent product, the integrated unit may be stored in a computer-readable storage medium. Based on such an understanding, the technical solutions of this application essentially, or the part contributing to other approaches, or all or some of the technical solutions may be implemented in the form of a software product. The computer software product is stored in a storage medium and includes several instructions for instructing a computer device (which may be a personal computer, a server, a network device, or the like) to perform all or some of the steps of the methods described in the embodiments of this application. The foregoing storage medium includes any medium that can store program code, such as a Universal Serial Bus (USB) flash drive, a removable hard disk, a read-only memory (ROM), a RAM, a magnetic disk, or an optical disc.

What is claimed is:

1. An estimation method comprising:
obtaining, during a preconfigured time interval, a current-moment charge/discharge current, a current-moment temperature, a current-moment coulomb capacity, and a previous-moment state of charge (SOC) value of a battery, wherein the preconfigured time interval is a first duration between a previous moment and a current moment;
obtaining a discharge duration of the battery, wherein the discharge duration is a second duration of a charge/discharge current;
determining a current-moment internal resistance response type of the battery based on the discharge duration;
determining current-moment internal resistance data of the battery based on the current-moment internal resistance response type, the current-moment temperature, the current-moment charge/discharge current, and the previous-moment SOC value;
determining a current-moment unusable capacity of the battery based on the current-moment internal resistance data, the current-moment charge/discharge current, and the current-moment temperature, wherein the current-moment unusable capacity is a first SOC value when the battery cannot release a capacity; and
determining a current-moment SOC value of the battery based on the current-moment coulomb capacity and the current-moment unusable capacity.

2. The estimation method of claim 1, further comprising further determining the current-moment internal resistance response type further based on a preconfigured first correspondence between the discharge duration and an internal resistance response type.

3. The estimation method of claim 2, wherein the preconfigured first correspondence comprises that:
the internal resistance response type is a first response type comprising an ohmic resistance when the discharge duration is less than or equal to a first threshold;
the internal resistance response type is a second response type comprising the ohmic resistance and a charge transfer resistance when the discharge duration is greater than the first threshold and less than or equal to a second threshold; and
the internal resistance response type is a third response type comprising the ohmic resistance, the charge transfer resistance, and a diffusional impedance when the discharge duration is greater than the second threshold.

4. The estimation method of claim 3, further comprising:
determining, based on the first response type, a second correspondence among the ohmic resistance, a first temperature of the battery, and a second SOC value of the battery; and
further determining the current-moment internal resistance data further based on the second correspondence, wherein the current-moment internal resistance data is a current-moment ohmic resistance.

5. The estimation method of claim 3, further comprising:
determining a second correspondence and a third correspondence based on the second response type, wherein the second correspondence is among the ohmic resistance, a first temperature of the battery, and a second SOC value of the battery, and wherein the third correspondence is among the charge transfer resistance, the first temperature, the second SOC value, and the charge/discharge current; and
further determining the current-moment internal resistance data further based on the second correspondence and the third correspondence, wherein the current-moment internal resistance data is a sum of a current-moment ohmic resistance and a current-moment charge transfer resistance.

6. The estimation method of claim 3, further comprising:
determining a second correspondence, a third correspondence, and a fourth correspondence based on the third response type, wherein the second correspondence is among the ohmic resistance, a first temperature of the battery, and a second SOC value of the battery, wherein the third correspondence is among the charge transfer resistance, the first temperature, the second SOC value, and the charge/discharge current, and wherein the fourth correspondence is among the diffusional impedance, the first temperature, the second SOC value, and the charge/discharge current; and
further determining the current-moment internal resistance data further based on the second correspondence, the third correspondence, and the fourth correspondence, wherein the current-moment internal resistance data is a sum of a current-moment ohmic resistance, a current-moment charge transfer resistance, and a current-moment diffusional impedance.

7. The estimation method of claim 1, further comprising:
determining a current-moment internal resistance voltage of the battery based on the current-moment internal resistance data and the current-moment charge/discharge current, wherein the current-moment internal resistance voltage is a voltage loss caused by an internal resistance of the battery;
determining a current-moment unusable voltage of the battery based on the current-moment internal resistance voltage and a preconfigured cutoff voltage; and
further determining the current-moment unusable capacity further based on the current-moment unusable voltage and a preconfigured fifth correspondence, wherein the preconfigured fifth correspondence is among an open-circuit voltage of the battery, a first temperature of the battery, and a second SOC value of the battery.

8. The estimation method of claim 7, further comprising:
determining an initial capacity based on a preconfigured full charge capacity, the previous-moment SOC value, and the preconfigured fifth correspondence, wherein the initial capacity is a previous-moment capacity of the battery;
determining a current-moment residual capacity of the battery based on the initial capacity, the current-moment coulomb capacity, and the current-moment unusable capacity; and
further determining the current-moment SOC value further based on the current-moment residual capacity and the preconfigured full charge capacity.

9. An estimation apparatus comprising:
a processor;
a current sensor coupled to the processor and configured to:
obtain a current-moment charge/discharge current of a battery; and
transmit the current-moment charge/discharge current to the processor;
a temperature sensor coupled to the processor and configured to:
obtain a current-moment temperature of the battery; and
transmit the current-moment temperature to the processor;
a coulombmeter coupled to the processor and configured to:
accumulate currents flowing through the battery to obtain a current-moment coulomb capacity; and
transmit the current-moment coulomb capacity to the processor;
a timer coupled to the processor and configured to:
obtain a discharge duration of the battery; and
transmit the discharge duration to the processor;
a memory coupled to the processor and configured to store parameter information of the battery, wherein the parameter information comprises a previous-moment state of charge (SOC) value,
wherein the processor is configured to estimate a current-moment SOC value of the battery based on the parameter information, the current-moment charge/discharge current, the current-moment temperature, and the current-moment coulomb capacity.

10. The estimation apparatus of claim 9, wherein the parameter information further comprises a first correspondence between the discharge duration and an internal resistance response type of the battery.

11. The estimation apparatus of claim 10, wherein the parameter information further comprises:
a second correspondence among an ohmic resistance of the battery, a first temperature of the battery, and a first SOC value of the battery;
a third correspondence among a charge transfer resistance of the battery, the first temperature, the first SOC value, and the current-moment charge/discharge current; and
a fourth correspondence among a diffusional impedance of the battery, the first temperature, the first SOC value, and the current-moment charge/discharge current.

12. An estimation apparatus comprising:
a memory configured to store instructions; and
a processor coupled to the memory, wherein the instructions cause the processor to be configured to:
obtain, during a preconfigured time interval, a current-moment charge/discharge current, a current-moment temperature, a current-moment coulomb capacity, and a previous-moment state of charge (SOC) value of a battery, wherein the preconfigured time interval is a first duration between a previous moment and a current moment;
obtain a discharge duration of the battery, wherein the discharge duration is a second duration of a charge/discharge current;
determine a current-moment internal resistance response type of the battery based on the discharge duration;
determine current-moment internal resistance data of the battery based on the current-moment internal resistance response type, the current-moment temperature, the current-moment charge/discharge current, and the previous-moment SOC value;
determine a current-moment unusable capacity of the battery based on the current-moment internal resistance data, the current-moment charge/discharge current, and the current-moment temperature, wherein the current-moment unusable capacity is a first SOC value when the battery cannot release a capacity; and
determine a current-moment SOC value of the battery based on the current-moment coulomb capacity and the current-moment unusable capacity.

13. The estimation apparatus of claim 12, wherein the instructions further cause the processor to be configured to determine the current-moment internal resistance response type further based on a preconfigured first correspondence, and wherein the preconfigured first correspondence is between the discharge duration and an internal resistance response type of the battery.

14. The estimation apparatus of claim 13, wherein the preconfigured first correspondence comprises that:
the internal resistance response type is a first response type that comprises an ohmic resistance when the discharge duration is less than or equal to a first threshold;
the internal resistance response type is a second response type that comprises the ohmic resistance and a charge transfer resistance when the discharge duration is greater than the first threshold and less than or equal to a second threshold; and
the internal resistance response type is a third response type that comprises the ohmic resistance, the charge transfer resistance, and a diffusional impedance when the discharge duration is greater than the second threshold.

15. The estimation apparatus of claim 14, wherein the instructions further cause the processor to be configured to:
determine a second correspondence based on the first response type, wherein the second correspondence is among the ohmic resistance, a first temperature of the battery, and a second SOC value of the battery; and
determine the current-moment internal resistance data further based on the second correspondence, wherein the current-moment internal resistance data is a current-moment ohmic resistance.

16. The estimation apparatus of claim 14, wherein the instructions further cause the processor to be configured to:
determine a second correspondence and a third correspondence based on the second response type, wherein the second correspondence is among the ohmic resistance, a first temperature of the battery, and a second SOC value of the battery, and wherein the third correspondence is among the charge transfer resistance, the first temperature, the second SOC value, and the charge/discharge current; and
determine the current-moment internal resistance data further based on the second correspondence and the third correspondence, wherein the current-moment internal resistance data is a sum of a current-moment ohmic resistance and a current-moment charge transfer resistance.

17. The estimation apparatus of claim 14, wherein the instructions further cause the processor to be configured to:
determine a second correspondence, a third correspondence, and a fourth correspondence based on the third response type, wherein the second correspondence is among the ohmic resistance, a first temperature of the battery, and a second SOC value of the battery, wherein the third correspondence is among the charge transfer resistance, the first temperature, the second SOC value, and the charge/discharge current, and wherein the fourth correspondence is among the diffusional impedance, the first temperature, the second SOC value, and the charge/discharge current; and
determine the current-moment internal resistance data further based on the second correspondence, the third correspondence, and the fourth correspondence, wherein the current-moment internal resistance data is a sum of a current-moment ohmic resistance, a current-moment charge transfer resistance, and a current-moment diffusional impedance.

18. The estimation apparatus of claim 12, wherein the instructions further cause the processor to be configured to:
determine a current-moment internal resistance voltage of the battery based on the current-moment internal resistance data and the current-moment charge/discharge current, wherein the current-moment internal resistance voltage is a voltage loss caused by an internal resistance of the battery;
determine a current-moment unusable voltage of the battery based on the current-moment internal resistance voltage and a preconfigured cutoff voltage; and
determine the current-moment unusable capacity further based on the current-moment unusable voltage and a preconfigured fifth correspondence, wherein the preconfigured fifth correspondence is among an open-circuit voltage of the battery, a first temperature of the battery, and a second SOC value of the battery.

19. The estimation apparatus of claim 18, wherein the instructions further cause the processor to be configured to:
determine an initial capacity based on a preconfigured full charge capacity, the previous-moment SOC value, and the preconfigured fifth correspondence, wherein the initial capacity is a previous-moment capacity of the battery;
determine a current-moment residual capacity of the battery based on the initial capacity, the current-moment coulomb capacity, and the current-moment unusable capacity; and
determine the current-moment SOC value further based on the current-moment residual capacity and the preconfigured full charge capacity.

20. A terminal comprising:
a battery; and
an estimation apparatus coupled to the battery and comprising:
a memory configured to store instructions; and
a processor coupled to the memory, wherein the instructions cause the processor to be configured to:
obtain, during a preconfigured time interval, a current-moment charge/discharge current, a current-moment temperature, a current-moment coulomb capacity, and a previous-moment state of charge (SOC) value of the battery, wherein the preconfigured time interval is a first duration between a previous moment and a current moment;
obtain a discharge duration of the battery, wherein the discharge duration is a second duration of a charge/discharge current;
determine a current-moment internal resistance response type of the battery based on the discharge duration;
determine current-moment internal resistance data of the battery based on the current-moment internal resistance response type, the current-moment temperature, the current-moment charge/discharge current, and the previous-moment SOC value;
determine a current-moment unusable capacity of the battery based on the current-moment internal resistance data, the current-moment charge/discharge current, and the current-moment temperature, wherein the current-moment unusable capacity is a first SOC value when the battery cannot release a capacity; and
determine a current-moment SOC value of the battery based on the current-moment coulomb capacity and the current-moment unusable capacity.
